(19) United States
(12) Patent Application Publication
(10) Pub. No.: US 2008/0266820 A1
(43) Pub. Date: Oct. 30, 2008

(54) SYSTEM FOR SUPPORTING AND ELECTRICALLY GROUNDING A COVER OF AN ELECTRONIC CONTROL MODULE

(76) Inventors: Vivek Amir Jairazbhoy, Farmington Hills, MI (US); Diane Marie Jett, Warren, MI (US); Bertrand Robert Mohr, Ann Arbor, MI (US); Robert Edward Belke, West Bloomfield, MI (US); Michael Timothy Dwyer, Canton, MI (US)

Correspondence Address: VISTEON/BRINKS HOFER GILSON & LIONE, 524 South Main Street, Suite 200, Ann Arbor, MI, 48104, US

(21) Appl. No.: 11/739,881

(22) Filed: Apr. 25, 2007

(51) Int. Cl. H05K 5/00

(52) U.S. Cl. 361/753; 174/255

(57) ABSTRACT

A system for supporting and electrically grounding metallic covers for electronic control modules includes a housing having wall portions defining a cavity with an opening, a circuit board located within the cavity, the circuit board having a ground plane formed within the circuit board, the circuit board having a top surface substantially facing the opening and supports for proving structural support for the cover, the supports being located on the top surface of the circuit board. The system shields emissions radiating from the module.

### BACKGROUND

1. Field of the Invention

The present invention generally relates to systems for supporting and electrically grounding metallic covers for electronic control modules.

2. Description of the Known Technology

Electronic control modules, such as those commonly found in automobiles, typically include a housing containing a circuit board. Generally, the housing has an opening large enough to easily place the circuit board within the housing. In order to protect the circuit board from environmental harm, a metallic cover is placed over the opening of the housing, thereby enclosing the circuit board within the housing.

In addition to protecting the circuit board from environmental harms, the metallic cover may also be utilized as a heat sink for dissipating heat generated by the circuit board. In order to accomplish this, the cover must be in thermal communication with the circuit board. Generally, this is accomplished by connecting one or more wires between the ground plane of the circuit board and the cover. By so doing, not only is the cover in thermal communication with the circuit board, but the wires electrically ground the cover, thereby shielding emissions radiating from the module. The primary drawback is the expense of manufacturing this system because of additional steps needed for attaching the wires to both the circuit board and the cover. Therefore, there is a need for a low cost system that places the cover in electrical and thermal communication with the circuit board.

### BRIEF SUMMARY

In satisfying the above need, as well as overcoming the enumerated drawbacks and other limitations of the known technology, the present invention provides a system for supporting and electrically grounding metallic covers for electronic control modules. The system generally includes a circuit board located within a cavity of a housing. Wall portions of the housing define an opening, wherein a cover is placed over the opening of the housing, thereby enclosing the circuit board.

The supports for supporting the cover when placed over the opening are located on a top side of the circuit board. The supports may be a solder ball formed on a mask opening of the circuit board, a plurality of wire spring members located on a contact portion formed adjacent to the perimeter of the top side of the circuit board or a plurality of spring members located adjacent to the perimeter of the circuit board.

Further objects, features and advantages of this invention will become readily apparent to persons skilled in the art after a review of the following description, with reference to the drawings and claims that are appended to and formed part of this specification.

### BRIEF DESCRIPTION OF THE DRAWINGS

FIG. 1 is a perspective view of an electronic control module embodying the principles of the present invention, wherein the supports is a solder ball formed on the surface of a mask opening of a circuit board;

FIG. 2 is a magnified view of the solder ball formed on the surface the mask opening;

FIG. 3 is a side view, generally taken along lines 3-3 of FIG. 2, of the solder ball and the mask opening;

FIG. 4 is a perspective view of another embodiment of the electronic control module embodying the principles of the present invention wherein the supports is a plurality of conductive wire spring members forming a compressible perimeter;

FIG. 5 is a side view of the conductive wire spring members generally taken along lines 5-5 of FIG. 4;

FIG. 6 is a side view similar to FIG. 5, wherein a cover mechanically engages the conductive wire spring members;

FIG. 7 is a perspective view of another embodiment of the electronic control module embodying the principles of the present invention, wherein the supports is a spring member; and

FIG. 8 is a magnified view of the spring member shown in FIG. 7.

### DETAILED DESCRIPTION

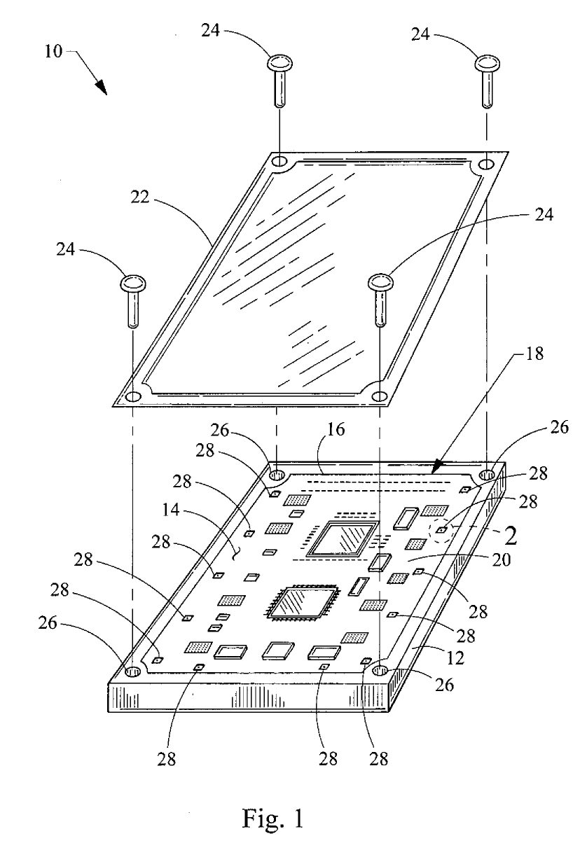

Referring to FIG. 1, an electronic control module 10 having a housing 12, a circuit board 18 and a cover 22 is shown. The housing 12 includes wall portions defining a cavity 14 and an opening 16. Located within the cavity 14 is the circuit board 18 having a top side 20 substantially facing the opening 16 of the housing 12.

The cover 22 covers the opening 16 of the housing 12, thereby enclosing the circuit board 18 within the cavity 14. The cover 22 is attached to the housing 12 via a series of fasteners 24 or other mechanisms that mechanically engage both the cover 22 and the housing 12. For example, the fasteners 24 may be threaded and engage a series of threaded holes 26 formed within the housing 12 and the cover 22. When assembled, the cover 22 seals the circuit board 18 within the cavity, protecting the circuit board 18 from external environmental elements.

The top side 20 of the circuit board 18 includes a plurality of supporting means or supports 28 that provide structural support to the cover 22. Additionally, the supports 28 may be in electrical communication with a ground plane formed within the circuit board 18. When the cover 22 is attached to the opening 16 of the housing 12, the cover 22 is electrically and mechanically in contact with the supports 28. By so doing, the cover 22 will be grounded to the ground plane of the circuit board 18, thereby shielding emissions radiating from the module 10. Additionally, the cover 22 can act as a heat sink for the circuit board 18, whereby heat generated by the circuit board 18 is transferred to the cover 22 via the supports 28. Furthermore, a dielectric spacing is formed between the cover 22 and the circuit board 18. This dielectric spacing may range between 2 to 20 thousandths of an inch (“mils”).

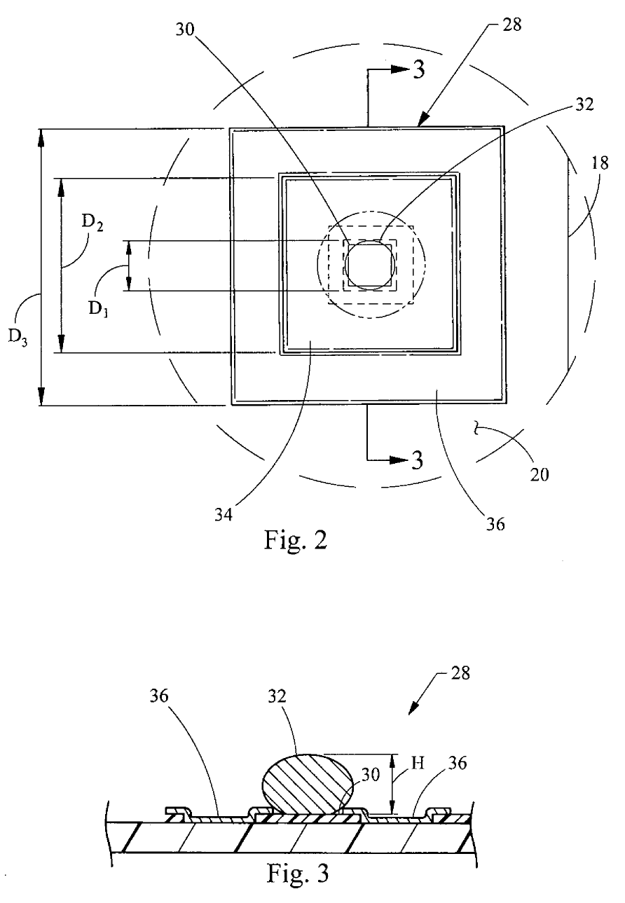

Referring to FIGS. 2 and 3, a magnified view of the supports 28 is shown. The supports 28 include a mask opening 30 in electrical communication with the ground plane of the circuit board 18. The mask opening 30 is a wettable surface. A solder ball 32, having a height being between 10 to 15 mils, preferably 12 mils in height, is formed on the surface of the mask opening 30 wherein the solder ball 32 is in electrical communication with both the ground plane of the circuit board 18 and the cover 22 as shown in FIG. 1.

Surrounding the mask opening 30 is a trough 36 made of a non wettable material. As particularly seen in FIG. 3, the lower surface of trough 36 has a lower elevation than the bond pad perimeter 34.

Preferably, the mask opening 30 and the bond pad perimeter 34 are substantially square in shape, however, any suitable shapes may be utilized. The width D1 of the mask opening 30 is approximately 28 mils, however this may vary between 15 and 35 mils. The width D2 of the bond pad perimeter 34 is approximately 68 mils. As stated previously, the trough 36 surrounds the bond pad perimeter 34 and is also generally square in shape, however, any suitable shape may be utilized. The dimension D3 across one side of the trough 36 in the above application is approximately 108 mils.

When the solder ball 32 is formed on the mask opening 30, excess solder remaining from the formation of the solder ball is repelled by the non-wetting bond pad perimeter 34 and received by the trough 36. For example, assume that a solder paste 38 is applied to an area covering the mask opening 30 and portions of the bond pad perimeter 34. The amount of solder paste 38 is critical. Too much solder paste (overprinting) would result in solder balling. Too little solder paste would not create a solder ball with a height of at least 10 mils. Generally, the ratio of the printed area (solder paste 38) to the solderable area (mask opening 30) should be between 1.2 and 2.4 to achieve the necessary critical height of at least 10 mils for the solder ball 38.

The solder paste 38 should completely cover the mask opening 30. If portions of the mask opening 30 are exposed, the solder ball 38 may be “robbed” of solder. Conversely, if too much solder paste 38 is used, the trough 36 may fill up with solder, increasing the possibility that excess solder would roll onto other portions of the circuit board 18.

When the solder paste 38 is heated to a molten state, the solder paste 38 will, by reflow action, form the solder ball 32 via the use of a stencil having a thickness between 3 to 7 mils. Any additional solder is repelled by the bond pad perimeter 34 and flows to the trough 36. By so doing, the height of the solder ball 32 can be consistently achieved because the mask opening 30 will retain a limited maximum amount of the molten solder. Assuming that the mask opening 30 of each supports 28 is of a consistent size, the height of each solder ball 32 will therefore be substantially the same. This is beneficial since having each solder ball at a consistent height, the plurality of supports 28 define a level support plane for the cover 22 that is of a specific and predictable height. The solder balls 38 may be placed in a staggered or aligned configuration and with a density dependant on the type of application. For example, in applications where thermal conductivity is important, additional solder balls 38 may be required to increase thermal conductivity.

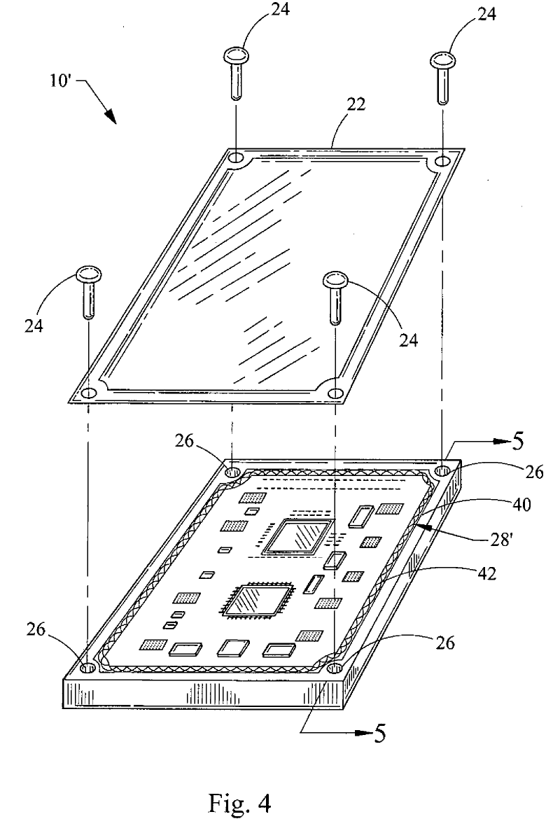

Referring to FIG. 4 another embodied of the module 10′ is shown. The module 10′ is similar to the module 10 shown in FIG. 1, however, the supports 28′ are different. The supports 28′ include a contact portion 40 formed adjacent to and extending around the perimeter of the circuit board 18. The contact portion 40 is generally in electrical communication with the ground plane of the circuit board 18. It should be understood that the contact portion 40 may only extend around portions of the perimeter of the circuit board 18.

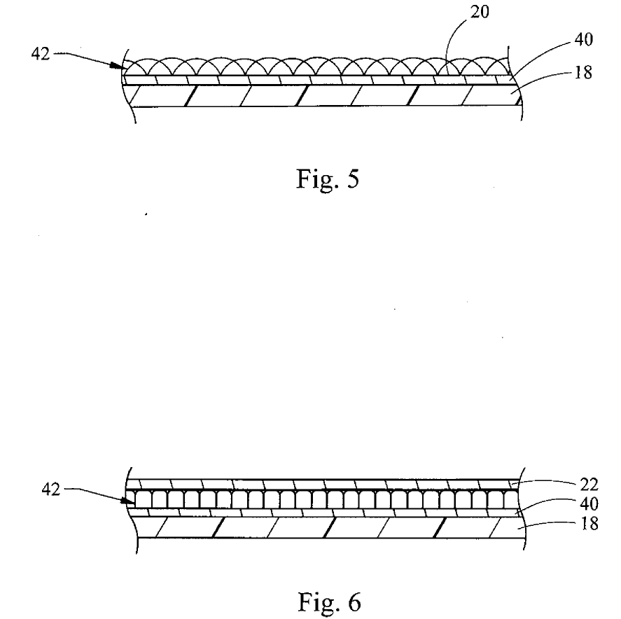

A plurality of conductive wire spring members 42 are attached to the contact portion 40. Generally, the conductive wire spring members 42 are made from tin, copper, gold, beryllium and combinations thereof. The conductive wire spring members 42 are ribbon bonds or wire bonds that form a compressible perimeter. As best shown in FIG. 5, when the cover 22 is not attached to the opening 16 of the housing 12, the conductive wire spring members 42 are in an uncompressed state. However, as shown in FIG. 6, when the cover 22 is attached to the opening 16 of the housing 12, the wire bonds are in a compressed state. When the wire bonds are in a compressed state, the wire bonds 42 are in electrical and mechanical communication with the cover 22. By so doing, the wire bonds 42 not only support the cover 22, but also can transfer thermal energy between the circuit board 18 and the cover 22. Additionally, the spring like construction of the wire bonds 42 bases and keeps the cover 22 in contact with the fasteners 24, preventing the cover 22 from moving.

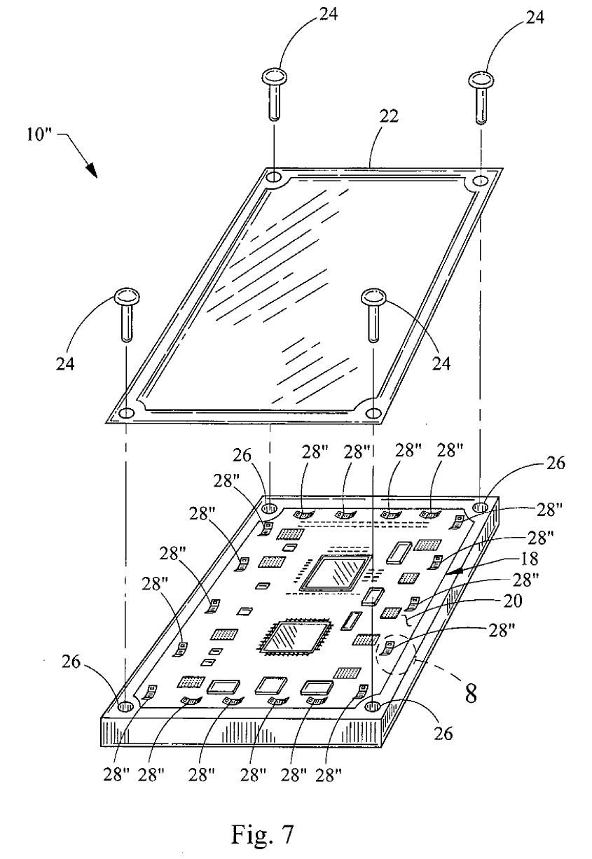

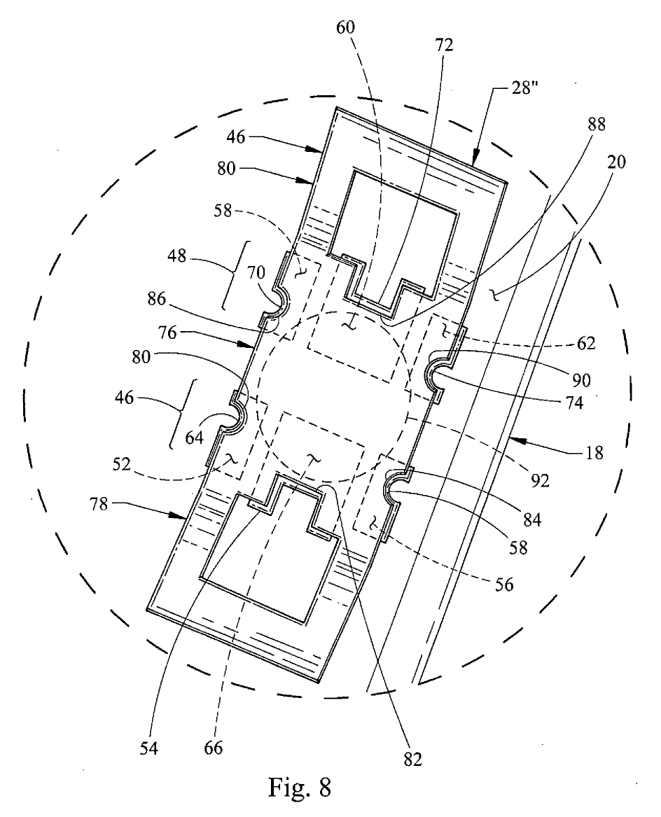

Referring to FIGS. 7 and 8, another embodiment of the module 10″ is shown. In this embodiment, the supports 28″ includes a first set of contact pads 46, a second set of contact pads 48 and a spring member 49. The spring member 49 is generally made from a copper alloy, such as a phosphor bronze. Additionally, the spring member 49 may be plated with tin or silver.

The first set of contact pads 46 includes an interior contact pad 52, a middle contact pad 54 and a side contact pad 56. In like manner, the second set of contact pads 48 includes a top contact pad 58, a middle contact pad 60 and a side contact pad 62. The contact pads of both the first and second sets 46, 48 are formed on or within the top side 18 of the circuit board 18 and are in electrical communication with the ground plane of the circuit board 18. While shown with three, it should be understood that any number of individual contact pads may be formed as part of the set of contact pads within the top side 18 of the circuit board 18. Notches 64, 66, 68 are formed in contact pads 52, 54, 56, respectively. In like matter, notches 70, 72, 74 are formed in the contact pads 58, 60, 62, respectively.

The spring member 46 generally includes base portion 76 fixedly attached to the top side 18 of the circuit board 18. The base portion 76 of the spring member 49 has notches 80, 82, 84, 86, 88, 90 formed within. The notches 64, 66, 68, 70, 72, 74 mechanically engage notches 80, 82, 84, 86, 88, 90, respectively. By having each pin mechanically engage a separate notch, the base portion of the spring member 49 can be held in place while being manufactured. Generally, solder paste 92 is deposited in and around the first and second sets 46, 48 of contact pads. The spring element 49 is then placed on top of the solder paste. When heat is applied to the solder paste, the solder paste melts 92 while the notches guide the spring member 49 into its appropriate location. Two generally opposing flexible portions 78, 80 extend from the base portion 76 away from the top side 20 of the circuit board 18. After the solder paste 92 cools, the spring member 49 is then fixedly attached to the circuit board 18.

Referring to FIG. 7, once the spring members 49 are fixedly attached to the circuit board 18, the spring members 49 form a compressible perimeter near the edges of the circuit board 18. When the cover 22 is not attached to the housing 12, the spring members 49 are in an uncompressed state. However, when the cover 22 is attached to the housing 12, spring members 49 are in a compressed state. When the spring members 49 are in a compressed state, the spring members 49 are in electrical and mechanical communication with the cover 22. By so doing, the spring members 49 not only support the cover 22, but also can transfer thermal energy between the circuit board 18 and the cover 22. Additionally, the spring like construction of the spring members 49 and keeps the cover 22 in contact with the fasteners 24, preventing the cover 22 from moving.

As a person skilled in the art will readily appreciate, the above description is meant as an illustration of implementation of the principles this invention. This description is not intended to limit the scope or application of this invention in that the invention is susceptible to modification, variation and change, without departing from the spirit of this invention, as defined in the following claims.

1. An electronic control module, the module comprising:
a housing having wall portions defining a cavity with an opening;
a circuit board located within the cavity, the circuit board having a ground plane formed within the circuit board, the circuit board having a top surface exposed within the opening;
a cover located over the opening and engaged with the housing; and
a plurality of conductive supports electrically grounding the cover and providing structural support for the cover, the supports being located on the top side of the circuit board.

2. The module of claim 1, wherein the plurality of supports further comprises:
a mask opening in electrical communication with the ground plane;
a solder ball formed on the surface of the mask opening, the solder ball being in electrical and thermal communication with the ground plane and the cover;
a bond pad perimeter; and
a trough surrounding the bond pad perimeter, the trough being of a lower elevation than the bond pad perimeter, whereby the trough receives excess solder produced when forming the solder ball.

3. The module of claim 2, wherein the bond pad perimeter surrounds the mask opening.

4. The module of claim 3, wherein the mask opening and bond pad perimeter are substantially square in shape.

5. The module of claim 4, wherein the mask opening has a width of about 15 to 35 mils.

6. The module of claim 4, wherein the bond pad perimeter has a width of about 108 mils.

7. The module of claim 2, wherein the solder ball is formed by applying a solder paste over the mask opening and the ratio between the area of the solder paste and the area of the mask opening is between about 1.2 and 2.4.

8. The module of claim 2, wherein the height of the solder ball is between about 10 mils to 15 mils.

9. The module of claim 1, wherein the supports are adjacent to the perimeter of the circuit board.

10. The module of claim 1, wherein the plurality of supports further comprises:
a contact portion, the contact portion formed adjacent the perimeter of the topside of the circuit board; and
a plurality of conductive wire spring members located on the contact portion, the conductive wire spring members being in electrical communication with the contact portion and the cover, whereby the plurality of conductive wire spring members form a compressible perimeter near the perimeter of the top surface of the circuit board.

11. The module of claim 10, wherein the contact portion is in electrical communication with the ground plane.

12. The module of claim 10, wherein the plurality of conductive wire spring members are ribbon bonds or wire bonds.

13. The module of claim 10, wherein the plurality of conductive wire spring members are made from aluminum tin, copper, gold, beryllium, metalized plastic and combinations thereof.

14. The module of claim 1, wherein the plurality of supports further comprises:
a contact pad in electrical communication with the ground plane; and
a spring member having a base portion and two generally opposing elastically compliant portions extending from the base portion, the base portion fixedly attached to the contact pad, the two generally opposing flexible portions extending away from the top surface of the circuit board.

15. The module of claim 14, wherein the plurality of supports are located adjacent to the perimeter of the circuit board.

16. The module of claim 15, wherein the length of the spring member is substantially parallel to the perimeter of the circuit board.

17. The module of claim 14, wherein the contact pad further comprises top, center and bottom contact pads, each of the top, center and bottom contact pads having a pin.

18. The module of claim 17, wherein:
the spring member further comprises top, center and bottom notches; and
the top, center and bottom notches mechanically engage the notches of the top, center and bottom contact pads, respectively, for aligning the spring member.

19. The module of claim 14, further comprising solder located between the base portion of the spring member and the contact pad, whereby the solder fixedly attaches the base portion of the spring member to the contact pad and aligns the spring member by capillary action.

20. The module of claim 14, wherein the spring member is made from an electrically conductive material.

21. The module of claim 20, wherein electrically the conductive material is a copper alloy.

22. The module of claim 14, wherein the spring element is plated with a conductive material.

23. The module of claim 2, wherein the solder ball is formed using a stencil having a thickness between about 3 mils to 7 mils.
